(19) United States
(12) Patent Application Publication
(10) Pub. No.: US 2026/0118601 A1
(43) Pub. Date: Apr. 30, 2026

(54) SEMICONDUCTOR STRUCTURE AND METHOD OF FORMING THE SAME

(71) Applicant: Taiwan Semiconductor Manufacturing Company, Ltd., Hsinchu (TW)

(72) Inventors: Chia-Hsin Chen, Tainan City (TW); Ming-Fa CHEN, Taichung City (TW)

(73) Assignee: Taiwan Semiconductor Manufacturing Company, Ltd., Hsinchu (TW)

(21) Appl. No.: 18/928,167

(22) Filed: Oct. 27, 2024

(51) Int. Cl. G02B 6/42; H01L 23/00; H01L 25/16

(52) U.S. Cl. CPC G02B 6/4206; H10W 90/00; H10W 80/312; H10W 80/327; H10W 90/792

(57) ABSTRACT

A semiconductor structure includes a photonic die and a conductive connector. The photonic die includes: an insulating layer having a first side and a second side; at least one optical element disposed on the first side of the insulating layer; a through via penetrating through the insulating layer and aside the at least one optical element, and having a metal is in direct contact with the insulating layer; and an interconnect structure disposed over the first side of the insulating layer and electrically connected to the through via. The conductive connector is disposed on the second side of the insulating layer and electrically connected to the through via. A critical dimension of the through via is between a critical dimension of the interconnect structure and a critical dimension of the conductive connector.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing semiconductor structures or packages have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 16B are schematic cross-sectional views of various stages in a method of forming a semiconductor structure according to some embodiments.

FIG. 17 to FIG. 22B are schematic cross-sectional views of various stages in a method of forming a semiconductor structure according to some embodiments.

FIG. 23 illustrates a flowchart of a method of forming a semiconductor structure according to some embodiments.

FIG. 24 illustrates a flowchart of a method of forming a semiconductor structure according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in physical contact, and may also include embodiments in which additional features may be formed between the first and second features, such that the first and second features may not be in physical contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose a semiconductor structure including a deep through via embedded in an insulating substrate rather than a semiconductor substrate. The deep through via of the disclosure is formed directly in the insulating substrate without forming the conventional insulating liner. The conventional insulating liner would cause charge accumulation when the deep through via is revealed by dry etching. The deep through via of the disclosure is formed with a simplified method, and is beneficial to prevent the charge accumulation issue. The deep through via of the disclosure may be applied to a photonic-electric integrated circuit (IC) package. With optical interconnection provided by the photonic structure, higher communication performance and more compact packaging can be easily achieved.

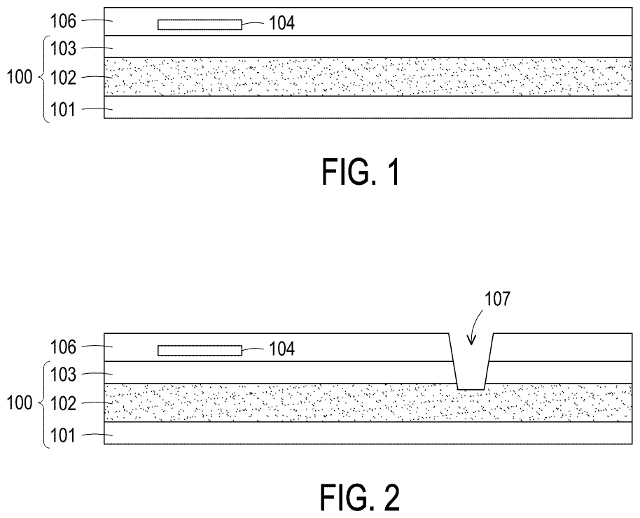

FIG. 1 to FIG. 16A are schematic cross-sectional views of various stages in a method of forming a semiconductor structure according to some embodiments. It is understood that the disclosure is not limited by the method described below. Additional operations can be provided before, during, and/or after the method and some of the operations described below can be replaced or eliminated, for additional embodiments of the methods. Although FIG. 1 to FIG. 16A are described in relation to a method, it is appreciated that the structures disclosed in FIG. 1 to FIG. 16A are not limited to such a method, but instead may stand alone as structures independent of the method.

Referring to FIG. 1, a composite substrate 100 is provided. In some embodiments, the composite substrate 100 includes, from bottom to top, a lower insulating layer 101, a semiconductor layer 102 and an upper insulating layer 103. Each of the lower insulating layer 101 and the upper insulating layer 103 may include silicon oxide, silicon oxynitiride, silicon oxycarbide, or the like. The semiconductor layer 102 may include an elementary semiconductor material including silicon and/or germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. In some embodiments, the method of forming the composite substrate 100 includes performing a thermal oxidizing process to a bulk semiconductor substrate, so that an oxide layer is formed on the top surface, the bottom surface and the sidewall of the bulk semiconductor substrate. Accordingly, the lower insulating layer 101 and the upper insulating layer 101 may include the same material. However, the disclosure is not limited thereto. In other embodiments, the method of forming the composite substrate 100 includes performing multiple deposition processes such as chemical vapor deposition (CVD) processes. Accordingly, the lower insulating layer 101 and the upper insulating layer 101 may include the same or different materials. In some embodiments, the thickness of each of the lower insulating layer 101, the semiconductor layer 102 and the upper insulating layer 103 ranges from about 0.2 μm to 3 μm.

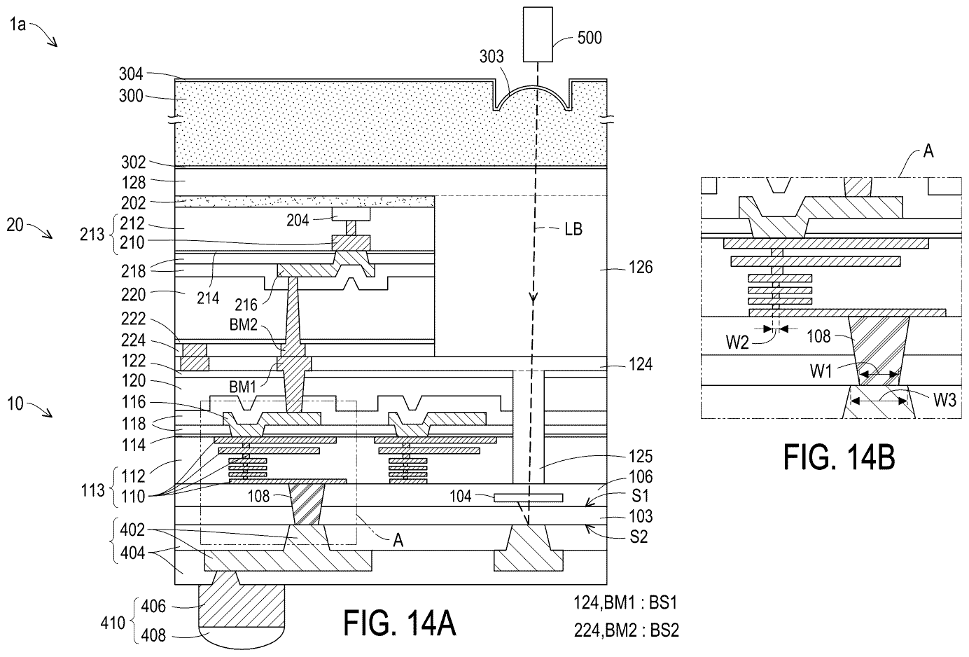

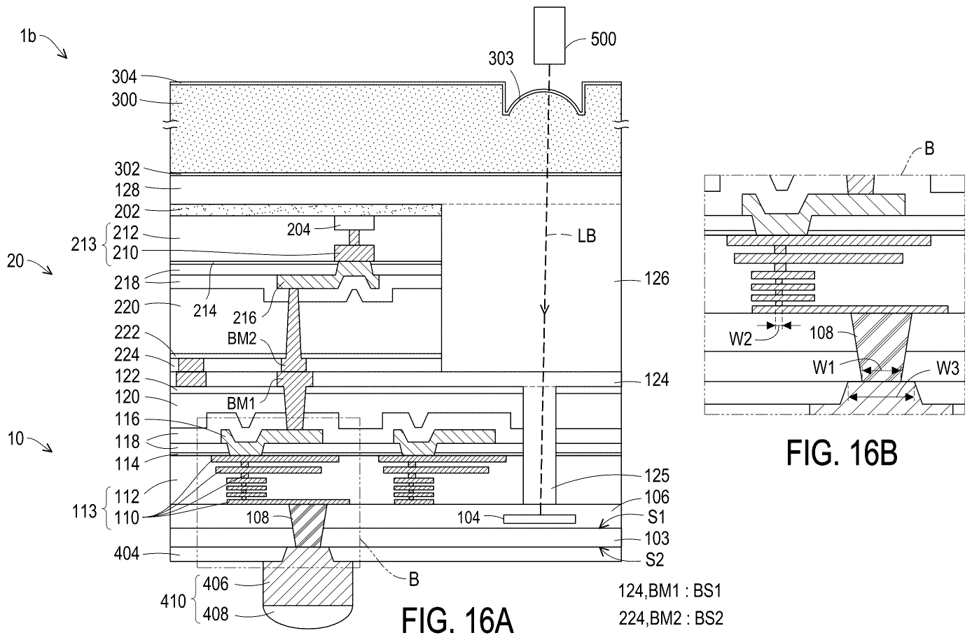

Thereafter, at least one optical element 104 is formed over the composite substrate 100 and embedded in an isolation layer 106. In some embodiments, the at least one optical element 104 includes an optical waveguide, a modulator, a detector, an optical coupler (e.g., grating coupler or edge coupler), a filter, the like or a combination thereof. In some embodiments, the optical element 104 includes an optical waveguide and a grating coupler when an optical fiber (see FIG. 14A or FIG. 16A) is disposed above the composite substrate 100. However, the disclosure is not limited thereto. In some embodiments, the optical element 104 includes an optical waveguide and an edge coupler when an optical fiber is disposed laterally aside the composite substrate 100, which will be described in other embodiments. The optical element 104 may include a dielectric material such as silicon nitride, an III-V material, a lithium niobate material, a polymer, or the like. The optical element 104 may be formed by depositing a material and patterning the material layer into a desired shape using one or more photolithographic masking and etching processes. The isolation layer 106 may include silicon oxide, silicon oxynitiride, silicon oxycarbide, or the like. In some embodiments, the thickness of the isolation layer 106 ranges from about 0.2 μm to 3 μm.

Referring to FIG. 2, a deep trench 107 is formed in the isolation layer 106, the upper insulating layer 103 and the semiconductor layer 102 and aside the optical element 104. Specifically, the deep trench 107 penetrates through the isolation layer 106 and the upper insulating layer 103 and extends into a portion of the semiconductor layer 102. The method of forming the deep trench 107 includes performing photolithographic masking and etching processes. In some embodiments, the depth of the deep trench 107 ranges from about 0.5 μm to 5 μm.

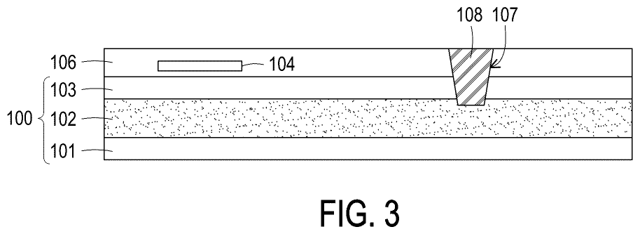

Referring to FIG. 3, a deep through via 108 is formed in the deep trench 107, and a conductive material (e.g., a metal or a metal-containing material) of the deep through via 108 is in direct contact with the isolation layer 106 and the upper insulating layer 103. The deep through via 108 may be referred to as a “through via”, “through dielectric via (TDV)” or a “through insulating via (TIV)” in some examples. Due to the sidewall of the deep through via 108 is surrounded by the isolation layer 106 and the upper insulating layer 103, the conventional insulating liner between the deep through via 108 and a semiconductor substrate is not required. Although a bottom portion of the deep through via 108 is in contact with the semiconductor layer 102, the bottom portion of the deep through via 108 and the semiconductor layer 102 will be removed in the subsequent processes, and thus, the conventional insulating liner is not required. Therefore, the process steps are simplified and the process cost is accordingly reduced. In some embodiments, the metal of the deep through via 108 include Cu, Al, Co, Cr, W, Ti, Ta, TiN, TaN, the like or a combination thereof. In some embodiments, the deep through via 108 is formed by performing a deposition process such as a sputtering process, followed by a planarization process (e.g., a CMP process and/or an etching back process). The deep through via 108 may be made by a single material such as W or TiN. In other embodiments, the deep through via 108 is formed by performing an electroplating process, followed by a planarization process (e.g., a CMP process and/or an etching back process). The deep through via 108 may have a multi-layer structure including a seed layer (e.g., Ti/Cu) and a metal layer (e.g., Cu). In some embodiments, the top surface of the deep through via 108 is coplanar with the top surface of the isolation layer 106. The deep through via 108 has an inclined sidewall. For example, the deep through via has a wide-top and narrow-bottom profile. However, the disclosure is not limited thereto. In other embodiments, the deep through via 108 has a substantially straight sidewall.

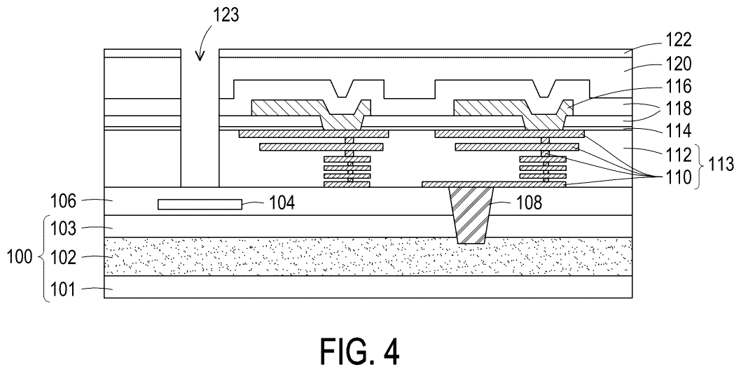

Referring to FIG. 4, an interconnect structure 113 is formed over the isolation layer 105 and electrically connected to the deep through via 108. The interconnect structure 113 includes metal features 110 embedded in dielectric layers 112. The metal features 110 include metal lines and metal vias electrically connected to each other. The metal features include Cu, Al, Co, Cr, W, Ti, Ta, TiN, TaN, the like or a combination thereof. The dielectric layers 112 include dielectric materials and etch stop materials between adjacent dielectric materials. The dielectric material includes silicon oxide, silicon oxynitride, silicon oxycarbide or a low-k material having a dielectric constant less than 3.5 or 2.5, and the etch stop material includes aluminum nitride, aluminum oxide, aluminum oxynitride, silicon nitride, silicon carbide or a combination thereof.

Thereafter, aluminum pads 116 are formed over and electrically connected to the interconnect structure 113 and embedded by passivation layers 118. The aluminum pads 116 are test pads, and some of them may have probe marks thereon. The passivation layers 118 may include a polymer material such as polybenzoxazole (PBO), polyimide (PI), benzocyclobutene (BCB), the like, or a combination thereof.

In some embodiments, an etch stop layer 114 is formed between the dielectric layer 112 and the passivation layer 118. The etch stop layer 114 may include aluminum nitride, aluminum oxide, aluminum oxynitride, silicon nitride, silicon carbide or a combination thereof.

Still referring to FIG. 4, an insulating layer 120 is formed over the passivation layers 114. The insulating layer 120 may include silicon oxide, silicon oxynitiride, silicon oxycarbide, or the like. In some embodiments, the insulating layer 120 is subjected to a planarization process (e.g., a CMP process and/or an etching back process), so as to provide a planar top surface for subsequent bonding process.

Afterwards, an etch stop layer 122 is formed over the insulating layer 120. The etch stop layer 122 may include aluminum nitride, aluminum oxide, aluminum oxynitride, silicon nitride, silicon carbide or a combination thereof.

Thereafter, a light path opening 123 is formed through the etch stop layer 122, the insulating layer 120, the passivation layers 118, the etch stop layer 114 and the dielectric layers 112, and therefore exposes the underlying isolation layer 106. The light path opening 123 corresponds to the optical element 104. The light path opening 123 is configured to fill a light-transparent material therein, so the light beam from an optical fiber to the optical element 104 is not affected by any opaque materials such as etch stop materials, passivation materials or the like. The light path opening 123 is formed by performing photolithographic masking and etching processes.

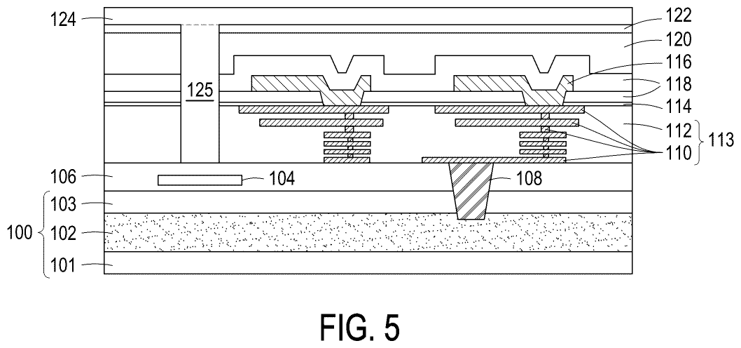

Referring to FIG. 5, a light-transparent material 125 is formed in the light path opening 123, and a bonding dielectric layer 124 is formed over the light-transparent material 125 and the etch stop layer 122. In some embodiments, the light-transparent material 125 and the bonding dielectric layer 124 are made by the same material (e.g., silicon oxide) and formed by the same deposition process (e.g., CVD process). In other embodiments, the light-transparent material 125 and the bonding dielectric layer 124 are made by different materials and formed by different deposition processes. For example, the light-transparent material 125 includes silicon oxide, and the bonding dielectric layer 124 includes silicon oxynitride. The light-transparent material 125 is referred to as an oxide bulk in some examples.

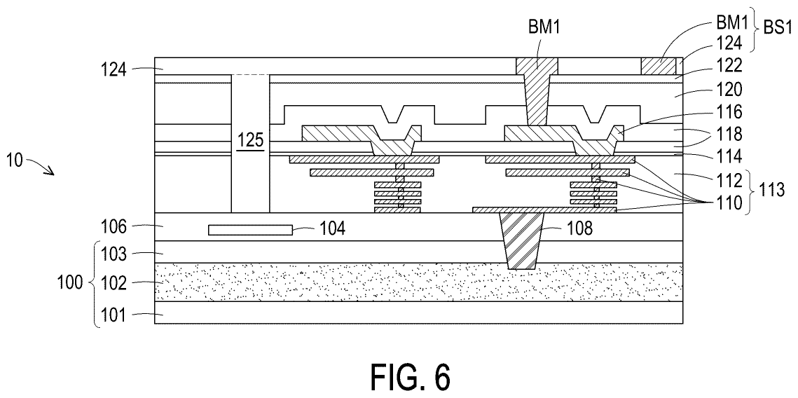

Referring to FIG. 6, bonding metal features BM1 are formed in the bonding dielectric layer 124. The bonding metal features BM1 include bonding pads and bonding vias electrically connected to each other. The bonding metal features BM1 include Cu, Al, Co, Cr, W, Ti, Ta, TiN, TaN, the like or a combination thereof. In some embodiments, at least one of the bonding metal features BM1 includes a bonding pad and an underlying bonding via, penetrating through the bonding dielectric layer 124, the etch stop layer 122, the insulating layer 120 and the passivation layer 118 and landed on the corresponding aluminum pad 116. In some embodiments, at least one of the bonding metal features BM1 is a dummy bonding pad without electrically connected to any electric component. The bonding metal features BM1 and the bonding dielectric layer 124 collectively constitute a bonding structure BS1. The photonic die 10 is thus completed.

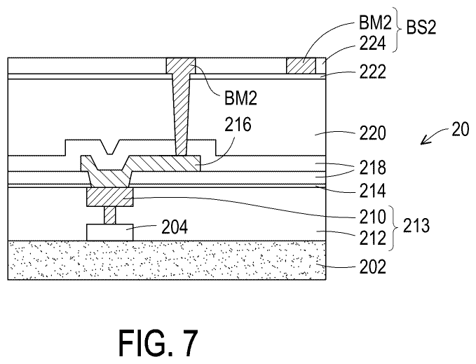

Referring to FIG. 7, an electronic die 20 is provided. In some embodiments, the electronic die 20 may include a semiconductor substrate 202, at least one electric device 204 on an active side (e.g., front side) of the semiconductor substrate 202, an interconnect structure 213 on the active side of the semiconductor substrate 202 and a bonding structure BS2. The semiconductor substrate 202 may be a substrate of silicon, doped or undoped or a semiconductor-on-insulator (SOI) substrate. The semiconductor substrate 202 may include an elementary semiconductor material including silicon and/or germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multilayered or gradient substrates, may also be used. The at least one electric device 204 may include active and/or passive devices.

The interconnect structure 213 includes metal features 210 embedded in dielectric layers 212. The metal features 210 include metal lines and metal vias electrically connected to each other. The metal features 210 include Cu, Al, Co, Cr, W, Ti, Ta, TiN, TaN, the like or a combination thereof. The dielectric layers 212 include dielectric materials and etch stop materials between adjacent dielectric materials. The dielectric material includes silicon oxide, silicon oxynitride, silicon oxycarbide or a low-k material having a dielectric constant less than 3.5 or 2.5, and the etch stop material includes aluminum nitride, aluminum oxide, aluminum oxynitride, silicon nitride, silicon carbide or a combination thereof.

Aluminum pads 216 are formed over and electrically connected to the interconnect structure 213 and embedded by passivation layers 218. The aluminum pads 216 are test pads, and some of them may have probe marks thereon. The passivation layers 218 may include a polymer material such as polybenzoxazole (PBO), polyimide (PI), benzocyclobutene (BCB), the like, or a combination thereof.

In some embodiments, an etch stop layer 214 is formed between the dielectric layer 212 and the passivation layer 218. The etch stop layer 214 may include aluminum nitride, aluminum oxide, aluminum oxynitride, silicon nitride, silicon carbide or a combination thereof.

An insulating layer 220 is formed over the passivation layers 214. The insulating layer 220 may include silicon oxide, silicon oxynitiride, silicon oxycarbide, or the like. In some embodiments, the insulating layer 220 is subjected to a planarization process (e.g., CMP process), so as to provide a planar top surface for subsequent bonding process.

Afterwards, an etch stop layer 222 is formed over the insulating layer 220. The etch stop layer 222 may include aluminum nitride, aluminum oxide, aluminum oxynitride, silicon nitride, silicon carbide or a combination thereof.

Thereafter, a bonding dielectric layer 224 is formed over the etch stop layer 222. In some embodiments, the bonding dielectric layer 124 includes silicon oxide or silicon oxynitride. Bonding metal features BM2 are formed in the bonding dielectric layer 224. The bonding metal features BM2 include bonding pads and bonding vias electrically connected to each other. The bonding metal features BM2 include Cu, Al, Co, Cr, W, Ti, Ta, TiN, TaN, the like or a combination thereof. In some embodiments, at least one of the bonding metal features BM2 includes a bonding pad and an underlying bonding via, penetrating through the bonding dielectric layer 224, the etch stop layer 222, the insulating layer 220 and the passivation layer 218 and landed on the corresponding aluminum pad 216. In some embodiments, at least one of the bonding metal features BM2 is a dummy bonding pad without electrically connected to any electric component. The bonding metal features BM2 and the bonding dielectric layer 224 collectively constitute a bonding structure BS2. The electronic die 20 is thus completed.

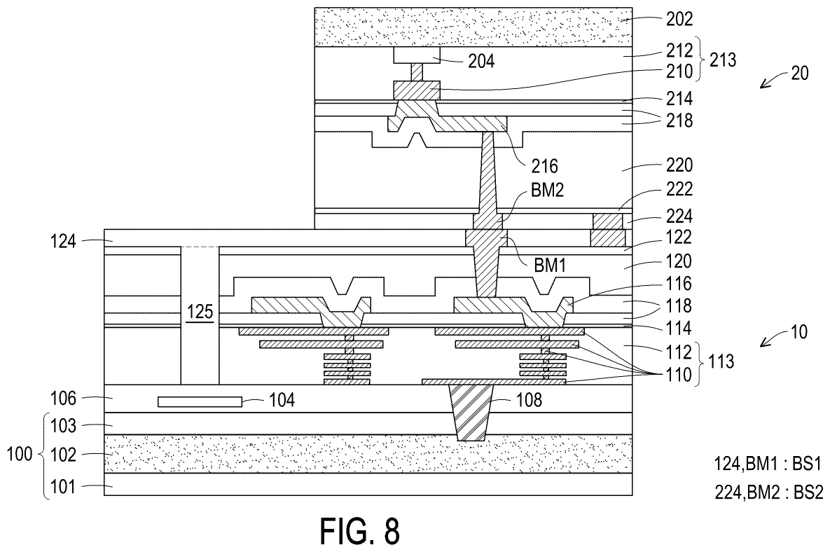

Referring to FIG. 8, the electronic die 20 is bonded to the photonic die 10 through a hybrid bonding including a metal-to-metal bonding and a dielectric-to-dielectric bonding. For example, the bonding metal features BM2 are bonded to the bonding metal features BM1, and the bonding dielectric layer 224 is bonded to the bonding dielectric layer 124. In some embodiments, the width of the bonding metal features BM2 is different from (e.g., greater than) the width of the bonding metal features BM1, but the disclosure is not limited thereto. In other embodiments, the width of the bonding metal features BM2 is substantially the same with the width of the bonding metal features BM1. In some embodiments, the material of the bonding dielectric layer 224 (e.g., silicon oxynitride) is different from the material of the bonding dielectric layer 214 (e.g., silicon oxide), but the disclosure is not limited thereto. In other embodiments, the material of the bonding dielectric layer 224 is the same as the material of the bonding dielectric layer 214.

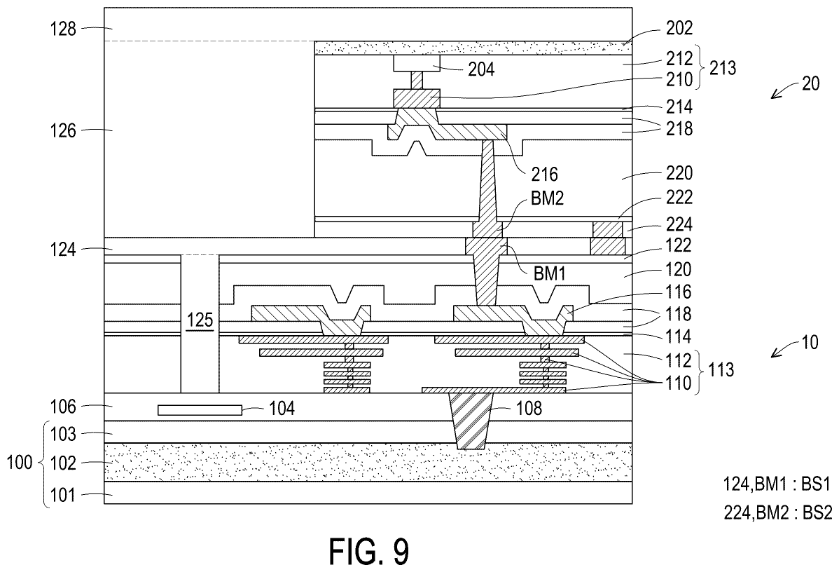

Referring to FIG. 9, a dielectric layer 126 is formed to encapsulate and cover the electronic die 20. The dielectric layer 126 may include a light-transparent material such as silicon oxide. In some embodiments, a thinning process is performed to the semiconductor substrate 202 of the electronic die 20, so as to reduce the thickness of the semiconductor substrate 202. The thinning process also removes a portion of the dielectric layer 126, so the remaining dielectric layer 126 is coplanar with the backside surface of the semiconductor substrate 202.

Thereafter, a dielectric layer 128 is formed over the dielectric layer 126 and the electronic die 20. The dielectric layer 128 may include a light-transparent material such as silicon oxide. In some embodiments, an interface does not exist or is hardly observed between the dielectric layer 126 and the dielectric layer 128.

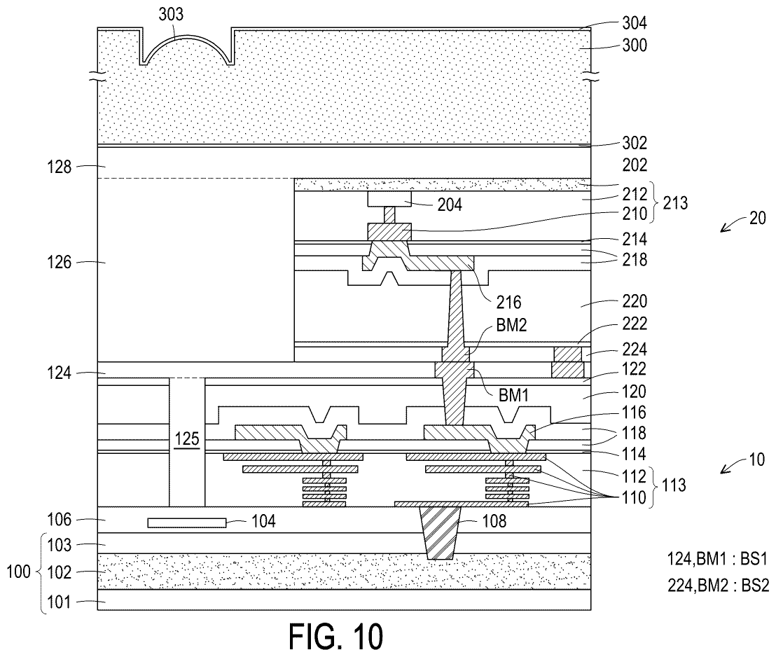

Referring to FIG. 10, a support die 300 is provided and bonded to the electronic die 20 through the dielectric layers 128 and 302 therebetween. In some embodiments, the support die 300 is a semiconductor die, such as a silicon die. The support die 300 may include an elementary semiconductor material including silicon and/or germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. In some embodiments, the support die 300 is also referred to as a support substrate, a silicon substrate or a carrier substrate. In some embodiments, the thickness of the support die 300 is much greater than the thickness of the electronic die 20 or the photonic die 10, so as to provide support for the whole structure. For example, the thickness of the support die 300 is greater than about 700 μm, and the thickness of the electronic die 20 or the photonic die 10 is less than about 100 μm.

In some embodiments, the support die 300 includes an optical lens 303. The optical lens 303 may be provided in the surface portion the support die 300 and disposed corresponding to the optical element 104 of the photonic die 10. Specifically, the optical lens 303 and the photonic die 10 are disposed at opposite sides of the electronic die 20. The optical lens 303 is configured to condense a light beam in a desired cross section, or focus a light beam in the desired direction. In some embodiments, the optical lens 303 has an optical recessed feature. In some embodiments, the optical lens 303 has a substantially vertical sidewall and a convex bottom. The shape of the optical lens 303 may be designed to have the desired curvature for focusing a light beam to the corresponding optical element 104.

In some embodiments, the support die 300 further includes dielectric layers 302 and 304 on opposite sides thereof. The dielectric layers 302 and 304 are anti-reflective dielectric layers. In some embodiments, each of the dielectric layers 302 and 304 includes silicon oxide layers and silicon nitride layers alternatively stacked.

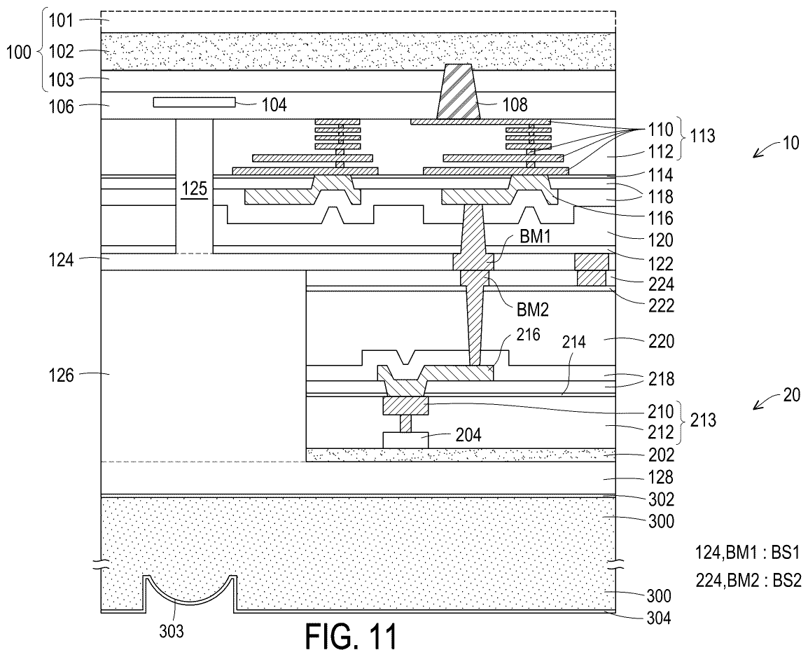

Referring to FIG. 11, the structure of FIG. 10 is turned over, so the composite substrate 100 faces up. Thereafter, the lower insulating layer 101 is removed from the composite substrate 100. The removing process may include a suitable etching process, such as a dry etching process.

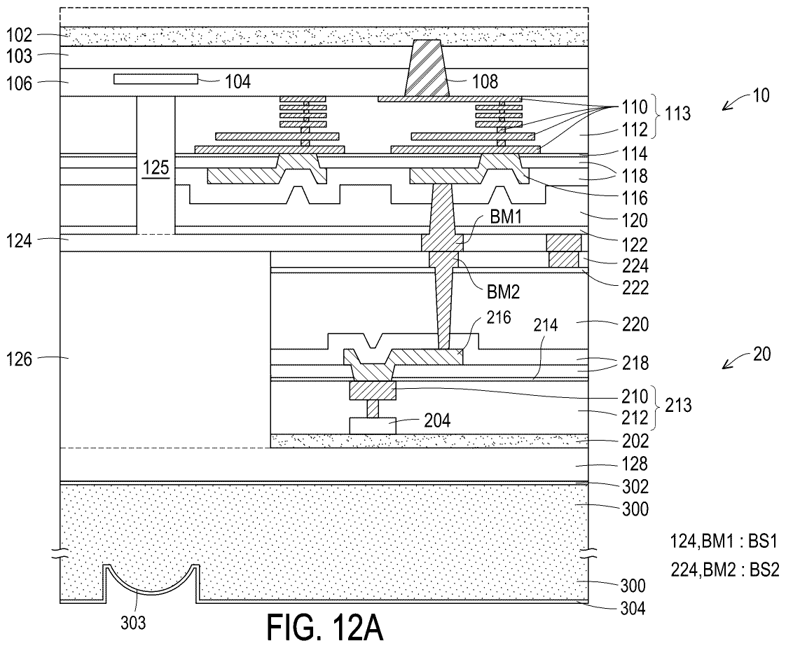

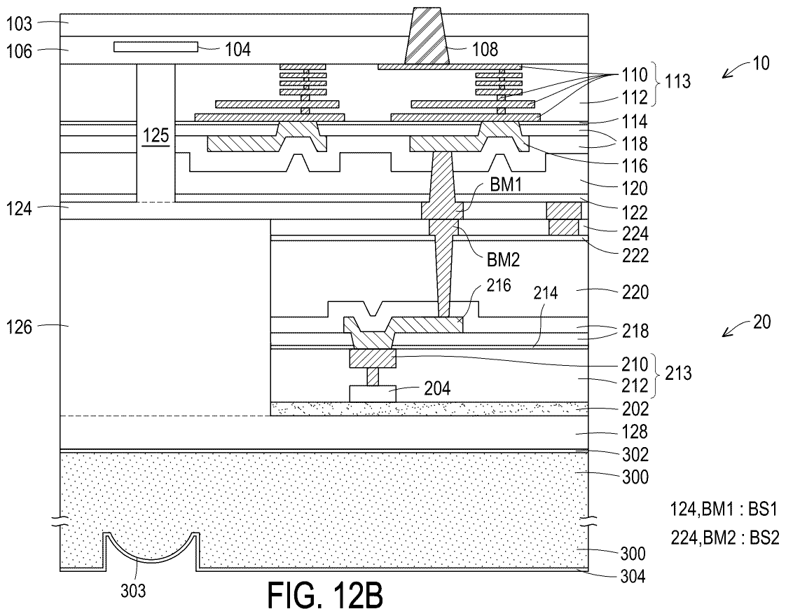

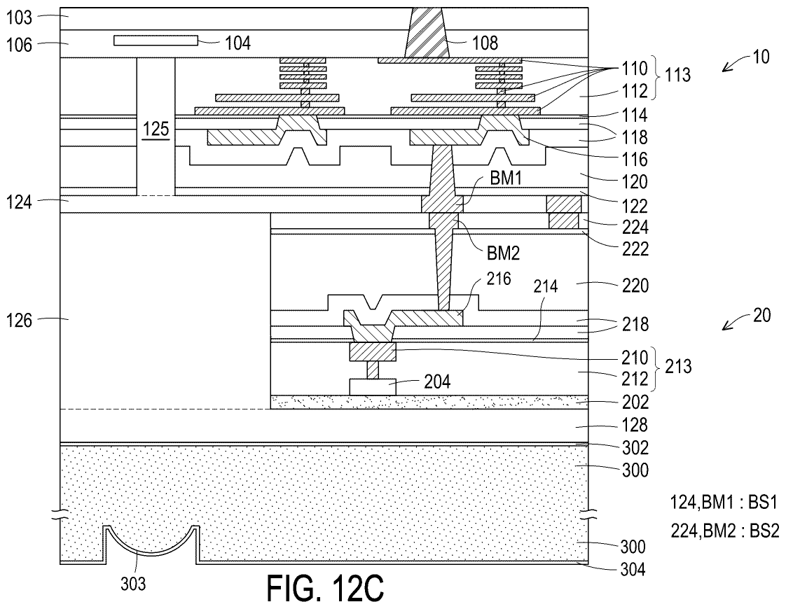

Referring to FIG. 12A to FIG. 12C, the semiconductor layer 102 and a portion of the deep through via 108 are removed, so the exposed surface of the upper insulating layer 103 is coplanar with the exposed surface of the deep through via 108. The removing process may include a suitable grinding process (e.g., CMP process) and/or an etching process (e.g., dry etching process). The conventional charge accumulation issue does occur around the deep through via due to lack of the conventional insulating liner.

In some embodiments, the semiconductor layer 102 and the portion of the deep through via 108 are removed by a multi-step process, as shown in FIG. 12A to FIG. 12C. First, the semiconductor layer 102 is partially removed, as shown in FIG. 12A. Thereafter, the semiconductor layer 102 is completely removed, so the deep through via 108 is protruded from the upper insulating layer 103, as shown in FIG. 12B. The protruded portion of the deep through via 108 is removed, so the exposed surface of the deep through via 108 is flush with the surface of the upper insulating layer 103, as shown in FIG. 12C.

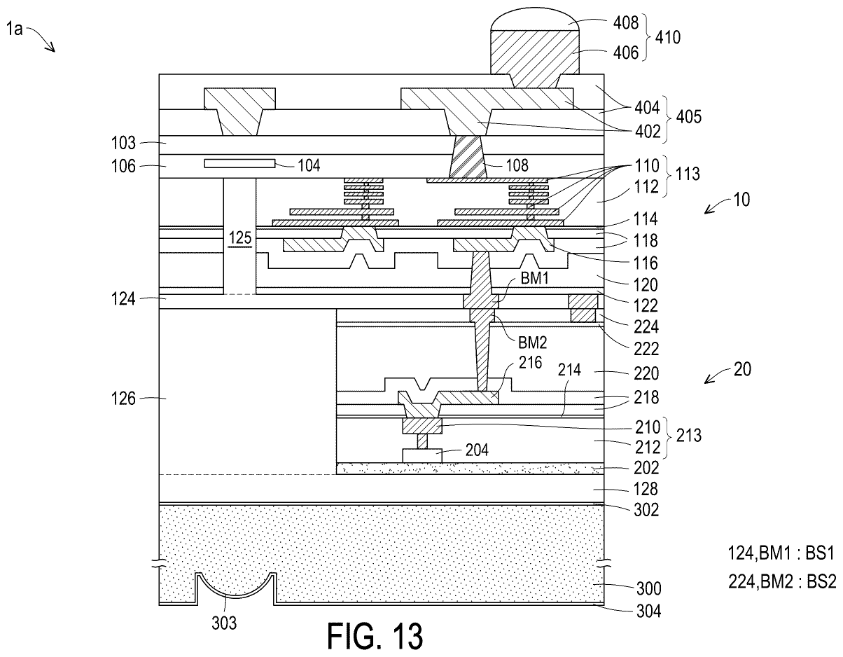

Referring to FIG. 13, a redistribution layer (RDL) structure 405 is formed over and electrically connected to the deep through via 108. The RDL structure 405 includes redistribution metal features 402 embedded in polymer layers 404. The redistribution metal features 402 include metal lines and metal vias electrically connected to each other. The redistribution features 402 include Cu, Al, Co, Cr, W, Ti, Ta, TiN, TaN, the like or a combination thereof. The polymer layers 404 include polybenzoxazole (PBO), polyimide (PI), benzocyclobutene (BCB), the like, or a combination thereof.

Thereafter, an under-bump metallization (UBM) pad 406 is formed through the polymer layer 404 and electrically connected to the RDL structure 405. The UBM pad 406 has a via portion embedded in the polymer layer 404 and a pad portion over the polymer layer 404. The UBM pad 406 includes Cu, Al, Co, Cr, W, Ti, Ta, TiN, TaN, the like or a combination thereof. Afterwards, a bump 408 is formed over and electrically connected to the UBM pad 406. In some embodiments, the bump 408 includes a metal pillar and/or a solder bump, which may be used for solder bonding. The UBM pad 406 and the bump 408 collectively constitute a conductive connector 410. The conductive connector 410 is referred to as a “bump structure” in some examples. The semiconductor structure 1a of the disclosure is thus completed. The semiconductor structure 1a may be electrically connected to an interposer through the conductive connector 410. A logic die and/or a memory die may be disposed over and electrically connected to the interposer aside the semiconductor structure 1a. The interposer may be electrically connected to a circuit board.

In the semiconductor structure 1a, the deep through via 108 is formed between and connected to the interconnect structure 113 and the RDL structure 405. Specifically, one end of the deep through via 108 is connected to a metal line of the interconnect structure 113, and the opposite end of the deep through via 108 is connected to a metal via of the RDL structure 405. Through the specification, the critical dimension (CD) is defined as the minimum target dimension, such as the line width of a wiring layer or the via width of a via layer. As shown in the enlarged view of FIG. 14B, the critical dimension (e.g., a via width W1) of the deep through via 108 is between the critical dimension (e.g., a via width W2) of the interconnect structure 113 and the critical dimension (e.g., a via width W3) of the RDL structure 405. In some embodiments, the ratio of the critical dimension of the interconnect structure 113 to the critical dimension of the deep through via 108 ranges from about 1:2 to 1:50, and the ratio of the critical dimension of the deep through via 108 to the critical dimension of the RDL structure 405 ranges from about 1:2 to 1:50. In some embodiments, the critical dimension of the interconnect structure 113 ranges from about 0.1 μm to 2.5 μm, the critical dimension of the deep through via 108 ranges from about 0.5 μm to 5 μm, and the critical dimension of the RDL structure 405 ranges from about 1 μm to 10 μm.

Referring to FIG. 14A, an optical fiber 500 is disposed over the photonic die 10 corresponding to the optical lens 303. In some embodiments, as shown in FIG. 14A, the light beam LB emitted from the optical fiber 500 over the photonic die 10 propagates through the optical lens 303 and the light-transparent material 125, and is optically coupled to the optical element 104 (e.g., grating coupler). In some embodiments, the light beam LB is reflected by the redistribution metal feature 402 (as a mirror) of the RDL structure 405 below the optical element 104, and then reflected back to the optical element 104. In some embodiments, the optical fiber 500 is arranged inclined with respect to the central axis of the optical lens 303. For example, the included angle between the optical fiber 500 and the central axis of the optical lens 303 is about 5 degrees to 15 degrees for improving the coupling efficiency.

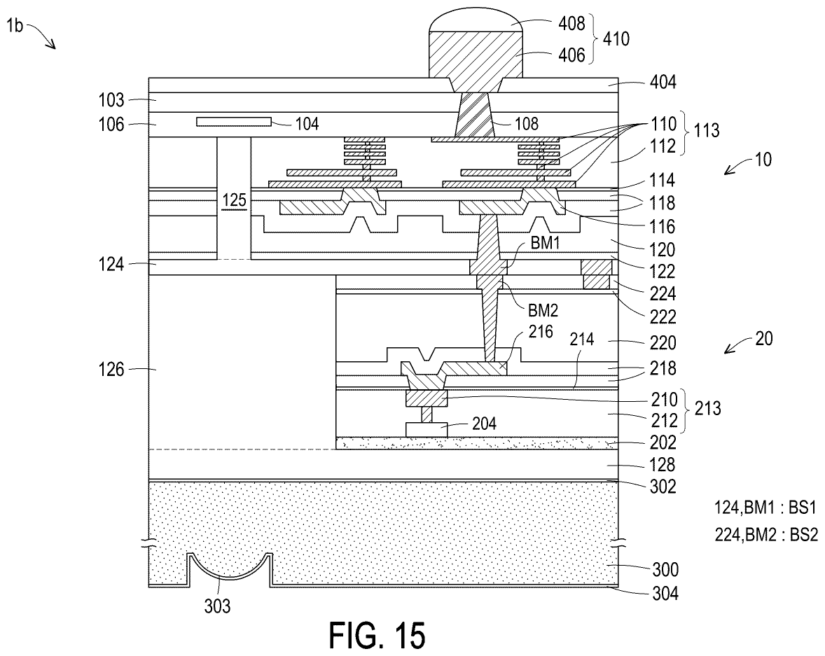

In some embodiments, the RDL structure 405 may be omitted from the semiconductor structure 1a, so as to form a semiconductor structure 1b. As shown in FIG. 15A, in the semiconductor structure 1b, the deep through via 108 is formed between and connected to a metal line of the interconnect structure 113 and the UBM pad 406 of the conductive connector 410. Through the specification, the critical dimension (CD) is defined as the minimum target dimension, such as the line width of a wiring layer or the via width of a via layer. As shown in the enlarged view of FIG. 16B, the critical dimension (e.g., a via width W1) of the deep through via 108 is between the critical dimension (e.g., a via width W2) of the interconnect structure 113 and the critical dimension (e.g., a via width W3) of the conductive connector 410. In some embodiments, the ratio of the critical dimension of the interconnect structure 113 to the critical dimension of the deep through via 108 ranges from about 1:2 to 1:50, and the ratio of the critical dimension of the deep through via 108 to the critical dimension of the conductive connector 410 (or the UBM pad 406) ranges from about 1:2 to 1:50. In some embodiments, the critical dimension of the interconnect structure 113 ranges from about 0.1 μm to 2.5 μm, the critical dimension of the deep through via 108 ranges from about 0.5 μm to 5 μm, and the critical dimension of the conductive connector 410 (or the UBM pad 406) ranges from about 1 μm to 10 μm.

Referring to FIG. 16A, an optical fiber 500 is disposed over the photonic die 10 corresponding to the optical lens 303. In some embodiments, as shown in FIG. 16A, the light beam LB emitted from the optical fiber 500 over the photonic die 10 propagates through the optical lens 303 and the light-transparent material 125, and is optically coupled to the optical element 104 (e.g., grating coupler). In some embodiments, the optical fiber 500 is arranged inclined with respect to the central axis of the optical lens 303. For example, the included angle between the optical fiber 500 and the central axis of the optical lens 303 is about 5 degrees to 15 degrees for improving the coupling efficiency.

The above embodiments in which an optical fiber 500 is disposed over the photonic die 10 are provided for illustration purposes, and are not construed as limiting the present disclosure. In other embodiments, an optical fiber may be disposed laterally adjacent to the photonic die 10.

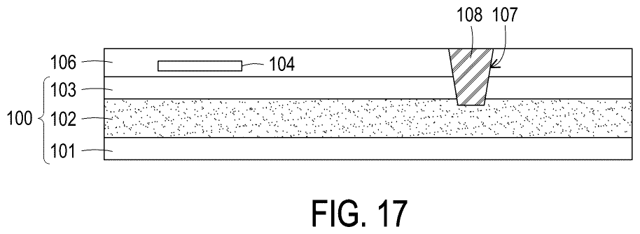

FIG. 17 to FIG. 22A are schematic cross-sectional views of various stages in a method of forming a semiconductor structure according to some embodiments. It is understood that the disclosure is not limited by the method described below. Additional operations can be provided before, during, and/or after the method and some of the operations described below can be replaced or eliminated, for additional embodiments of the methods. Although FIG. 17 to FIG. 22A are described in relation to a method, it is appreciated that the structures disclosed in FIG. 17 to FIG. 22A are not limited to such a method, but instead may stand alone as structures independent of the method.

The method of FIG. 17 to FIG. 22A is similar to the method of FIG. 1 to FIG. 16A, so the difference between them is described below, and the similarity is not iterated herein. In the description of respective drawings, similar reference numerals designate similar elements. The materials, forming methods and configurations of elements in FIG. 17 to FIG. 22A may refer to the materials, forming methods and configurations of similar elements described in FIG. 1 to FIG. 16A, so the details are not iterated herein.

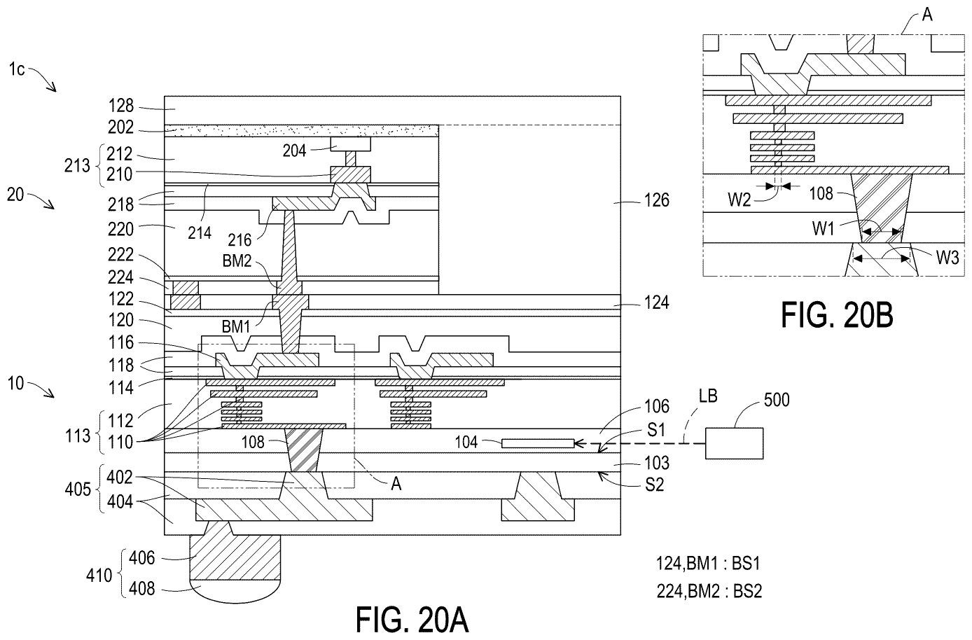

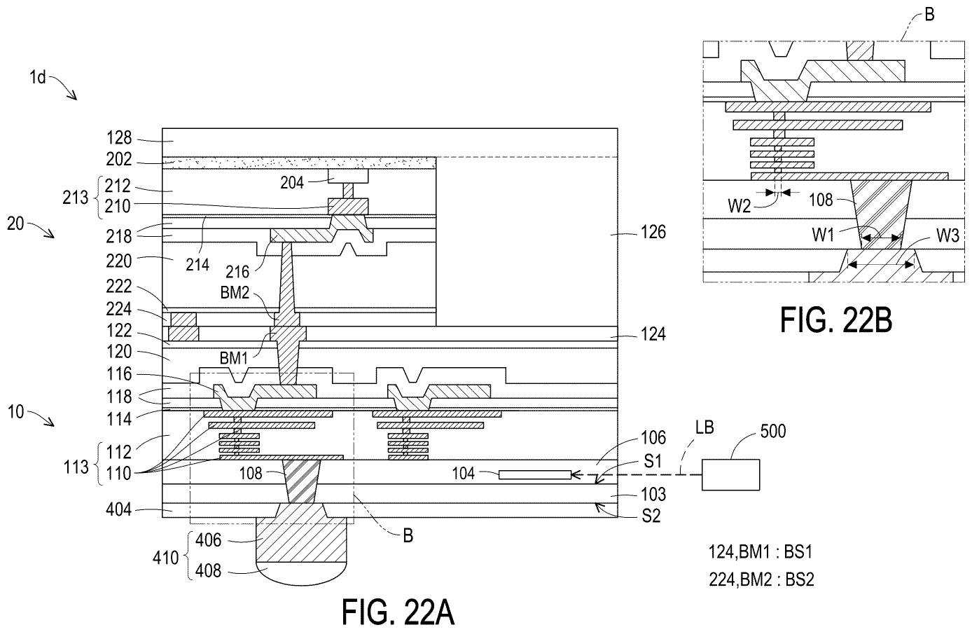

Referring to FIG. 17, a composite substrate 100 is provided. In some embodiments, the composite substrate 100 includes, from bottom to top, a lower insulating layer 101, a semiconductor layer 102 and an upper insulating layer 103. Thereafter, at least one optical element 104 is formed over the composite substrate 100 and embedded in an isolation layer 106. In some embodiments, the optical element 104 includes an optical waveguide and an edge coupler when an optical fiber (see FIG. 20A or FIG. 22A) is disposed laterally aside the composite substrate 100.

Afterwards, a deep trench 107 is formed in the isolation layer 106, the upper insulating layer 103 and the semiconductor layer 102 and aside the optical element 104. A deep through via 108 is then formed in the deep trench 107, wherein a metal of the deep through via 108 is in direct contact with the isolation layer 106 and the upper insulating layer 103.

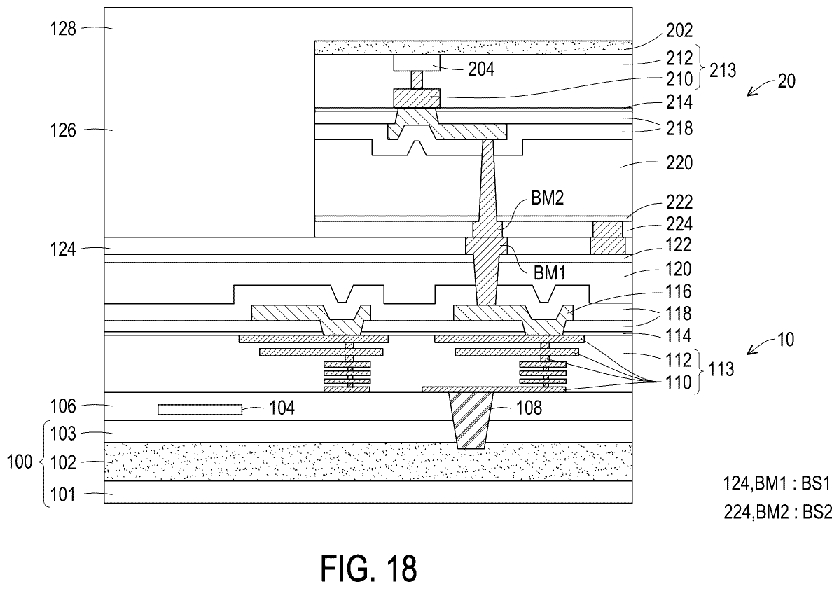

Referring to FIG. 18, an interconnect structure 113 is formed over the isolation layer 105 and electrically connected to the deep through via 108. Thereafter, aluminum pads 116 are formed over and electrically connected to the interconnect structure 113 and embedded by passivation layers 118. A bonding structure BS1 is formed over and electrically connected to the corresponding aluminum pads 116, so as to provide a photonic die 10.

Afterwards, an electric die 20 is provided and bonded to the photonic die 10 through a hybrid bonding. A dielectric layer 126 is formed over the photonic die 10 and encapsulates the electronic die 20, and a dielectric layer 128 is formed over the dielectric layer 126 and the electronic die 20.

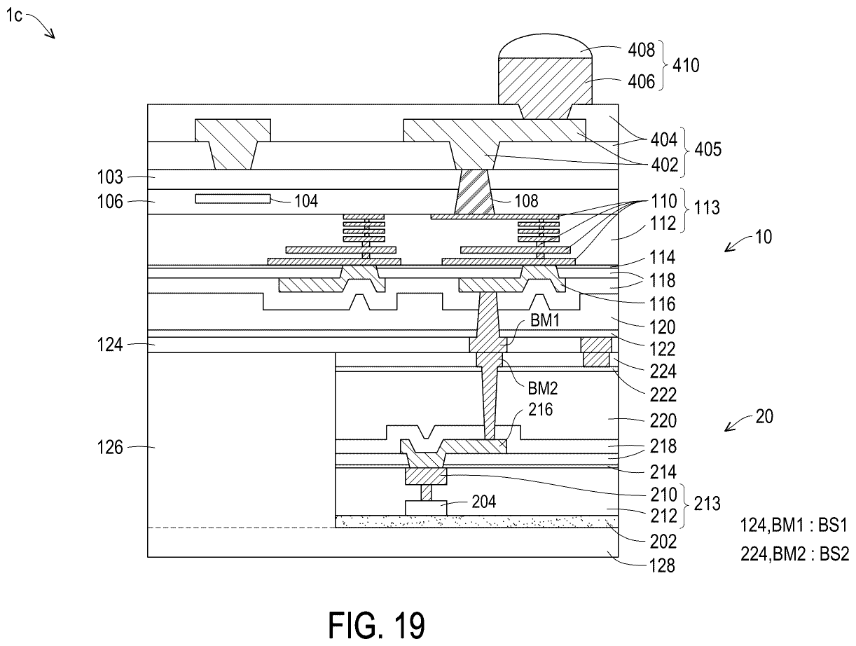

Referring to FIG. 19, the lower insulating layer 101 is removed from the composite substrate 100. Thereafter, the semiconductor layer 102 and a portion of the deep through via 108 are removed, so the exposed surface of the upper insulating layer 103 is coplanar with the exposed surface of the deep through via 108. The removing process may include a suitable grinding process (e.g., CMP process) and/or an etching process (e.g., dry etching process). The conventional charge accumulation issue does occur around the deep through via due to lack of the conventional insulating liner.

A redistribution layer (RDL) structure 405 is formed over and electrically connected to the deep through via 108. Thereafter, an under-bump metallization (UBM) pad 406 is formed over and electrically connected to the RDL structure 405. Afterwards, a bump 408 is formed over and electrically connected to the UBM pad 406. The UBM pad 406 and the bump 408 collectively constitute a conductive connector 410. The semiconductor structure 1c of the disclosure is thus completed. The semiconductor structure 1c may be electrically connected to an interposer through the conductive connector 410. A logic die and/or a memory die may be disposed over and electrically connected to the interposer aside the semiconductor structure 1a. The interposer may be electrically connected to a circuit board.

In the semiconductor structure 1c, the deep through via 108 is formed between and connected to the interconnect structure 113 and the RDL structure 405. Specifically, one end of the deep through via 108 is connected to a metal line of the interconnect structure 113, and the opposite end of the deep through via 108 is connected to a metal via of the RDL structure 405. As shown in the enlarged view of FIG. 20B, the critical dimension (e.g., a via width W1) of the deep through via 108 is between the critical dimension (e.g., a via width W2) of the interconnect structure 113 and the critical dimension (e.g., a via width W3) of the RDL structure 405. In some embodiments, the ratio of the critical dimension of the interconnect structure 113 to the critical dimension of the deep through via 108 ranges from about 1:2 to 1:50, and the ratio of the critical dimension of the deep through via 108 to the critical dimension of the RDL structure 405 ranges from about 1:2 to 1:50. In some embodiments, the critical dimension of the interconnect structure 113 ranges from about 0.1 μm to 2.5 μm, the critical dimension of the deep through via 108 ranges from about 0.5 μm to 5 μm, and the critical dimension of the RDL structure 405 ranges from about 1 μm to 10 μm.

Referring to FIG. 20A, an optical fiber 500 is disposed laterally aside the photonic die 10 corresponding to the optical element 104. In some embodiments, as shown in FIG. 20A, the light beam LB emitted from the optical fiber 500 beside the photonic die 10 propagates through the isolation layer 106, and is optically coupled to the optical element 104 (e.g., edge coupler).

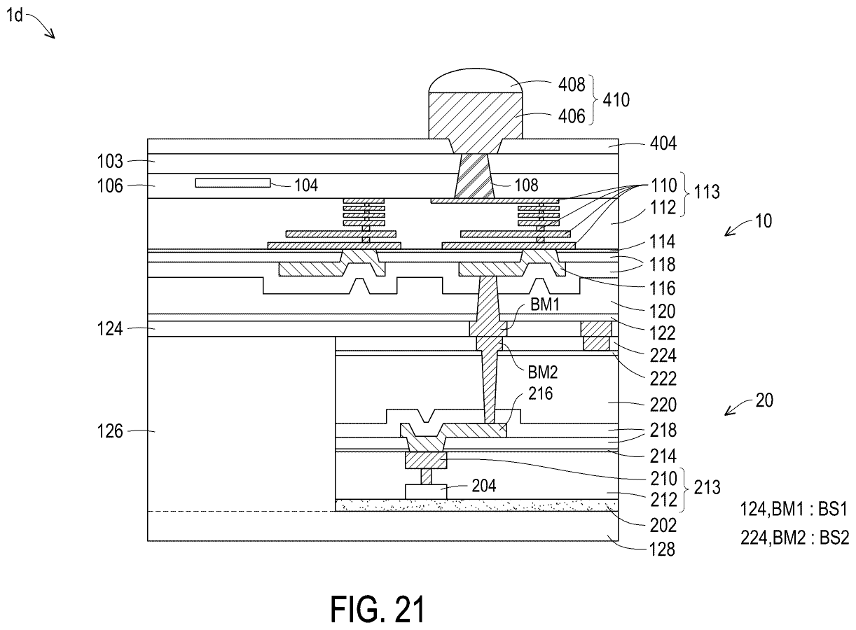

In some embodiments, the RDL structure 405 may be omitted from the semiconductor structure 1c, so as to form a semiconductor structure 1d. As shown in FIG. 21, in the semiconductor structure 1d, the deep through via 108 is formed between and connected to a metal line of the interconnect structure 113 and the UBM pad 406 of the conductive connector 410. As shown in the enlarged view of FIG. 22B, the critical dimension(e.g., a via width W1) of the deep through via 108 is between the critical dimension (e.g., a via width W2) of the interconnect structure 113 and the critical dimension (e.g., a via width W3) of the conductive connector 410. In some embodiments, the ratio of the critical dimension of the interconnect structure 113 to the critical dimension of the deep through via 108 ranges from about 1:2 to 1:50, and the ratio of the critical dimension of the deep through via 108 to the critical dimension of the conductive connector 410 (or the UBM pad 406) ranges from about 1:2 to 1:50. In some embodiments, the critical dimension of the interconnect structure 113 ranges from about 0.1 μm to 2.5 μm, the critical dimension of the deep through via 108 ranges from about 0.5 μm to 5 μm, and the critical dimension of the conductive connector 410 (or the UBM pad 406) ranges from about 1 μm to 10 μm.

Referring to FIG. 22A, an optical fiber 500 is disposed laterally aside the photonic die 10 corresponding to the optical element 104. In some embodiments, as shown in FIG. 21, the light beam LB emitted from the optical fiber 500 beside the photonic die 10 propagates through the isolation layer 106, and is optically coupled to the optical element 104 (e.g., edge coupler).

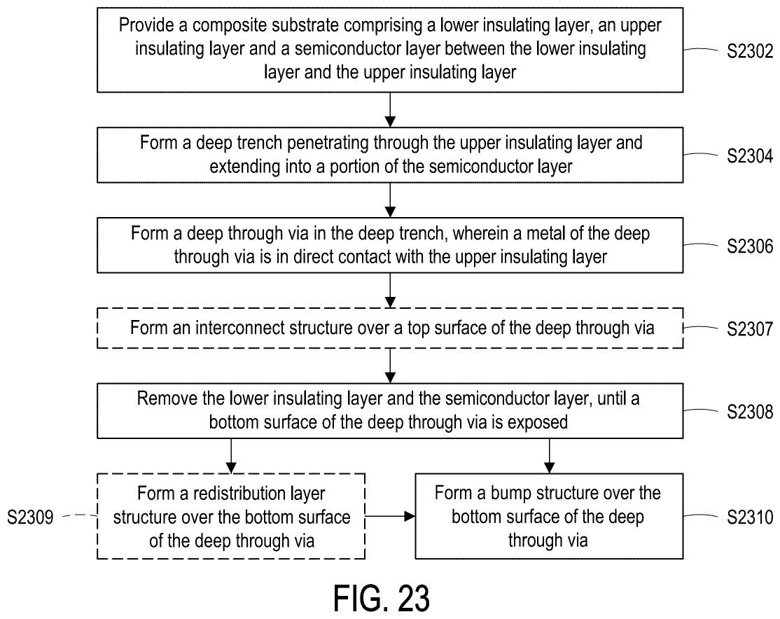

FIG. 23 illustrates a flowchart of a method of forming a semiconductor structure according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other unillustrated acts or events may be included.

At act S2302, a composite substrate is provided, and the composite substrate includes a lower insulating layer, an upper insulating layer and a semiconductor layer between the lower insulating layer and the upper insulating layer. FIG. 1 and FIG. 17 illustrate views corresponding to some embodiments of act S2302.

At act S2304, a deep trench is formed to penetrate through the upper insulating layer and extend into a portion of the semiconductor layer. FIG. 2 and FIG. 17 illustrate views corresponding to some embodiments of act S2304.

At act S2306, a deep through via is formed in the deep trench, wherein a metal of the deep through via is in direct contact with the upper insulating layer. FIG. 3 and FIG. 17 illustrate views corresponding to some embodiments of act S2306. In some embodiments, the deep through via is formed by a deposition process. In some embodiments, the deep through via is formed by an electroplating process.

At act S2307, an interconnect structure is formed over a top surface of the deep through via. FIG. 4 and FIG. 18 illustrate views corresponding to some embodiments of act S2307. In some embodiments, act S2307 is optional and may be omitted as needed.

At act S2308, the lower insulating layer and the semiconductor layer are removed, until a bottom surface of the deep through via is exposed. FIG. 11, FIG. 12 and FIG. 19 illustrate views corresponding to some embodiments of act S2308. In some embodiments, the bottom surface of the deep through via is flush with a bottom surface of the upper insulating layer.

At act S2309, a redistribution layer structure is formed over the bottom surface of the deep through via. FIG. 13 and FIG. 19 illustrate views corresponding to some embodiments of act S2309. In some embodiments, a critical dimension of the deep through via is between a critical dimension of the interconnect structure and critical dimension of the redistribution layer structure. In some embodiments, act S2309 is optional and may be omitted as needed.

At act S2310, a conductive connector is formed over the bottom surface of the deep through via. FIG. 13, FIG. 15, FIG. 19 and FIG. 21 illustrate views corresponding to some embodiments of act S2310.

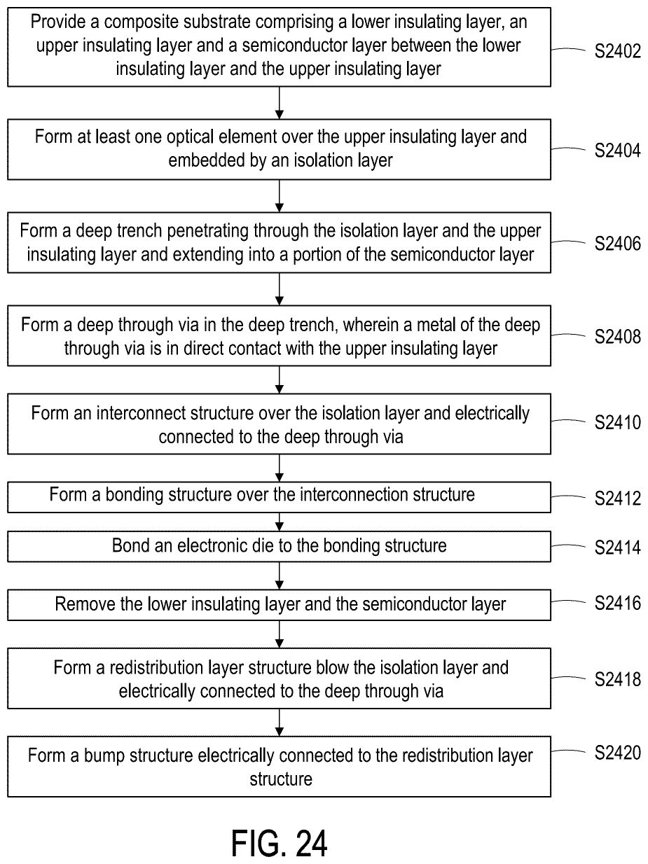

FIG. 24 illustrates a flowchart of a method of forming a semiconductor structure according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other unillustrated acts or events may be included.

At act S2402, a composite substrate is provided, and the composite substrate includes a lower insulating layer, an upper insulating layer and a semiconductor layer between the lower insulating layer and the upper insulating layer. FIG. 1 and FIG. 17 illustrate views corresponding to some embodiments of act S2402.

At act S2404, at least one optical element is formed over the upper insulating layer and embedded by an isolation layer. FIG. 1 and FIG. 17 illustrate views corresponding to some embodiments of act S2404.

At act S2406, a deep trench is formed to penetrate through the isolation layer and the upper insulating layer and extend into a portion of the semiconductor layer. FIG. 2 and FIG. 17 illustrate views corresponding to some embodiments of act S2406. In some embodiments, the deep trench further extends into the semiconductor layer of composite substrate.

At act S2408, a deep through via is formed in the deep trench, wherein a metal of the deep through via is in direct contact with the upper insulating layer. FIG. 3 and FIG. 17 illustrate views corresponding to some embodiments of act S2408.

At act S2410, an interconnect structure is formed over the isolation layer and electrically connected to the deep through via. FIG. 4 and FIG. 18 illustrate views corresponding to some embodiments of act S2410.

At act S2412, a bonding structure is formed over the interconnection structure. FIG. 5, FIG. 6 and FIG. 18 illustrate views corresponding to some embodiments of act S2412.

At act S2414, an electronic die is bonded to the bonding structure. FIG. 7, FIG. 8 and FIG. 18 illustrate views corresponding to some embodiments of act S2414.

At act S2416, the lower insulating layer and the semiconductor layer are removed. FIG. 11, FIG. 12 and FIG. 19 illustrate views corresponding to some embodiments of act S2416. In some embodiments, Act S2416 further removes a portion of the deep through via, so a bottom surface of the deep through via is flush with a bottom surface of the lower insulating layer.

At act S2418, a redistribution layer structure is formed blow the isolation layer and electrically connected to the deep through via. FIG. 13 and FIG. 19 illustrate views corresponding to some embodiments of act S2418.

At act S2420, a conductive connector is formed to electrically connect to the redistribution layer structure. FIG. 13, FIG. 15, FIG. 19 and FIG. 21 illustrate views corresponding to some embodiments of act S2420.

The semiconductor structures of the disclosure are illustrated below with reference to FIG. 13 to FIG. 16B and FIG. 19 to FIG. 22B. In some embodiments, a semiconductor structure 1a/1b/1c/1d includes a photonic die 10 and a conductive connector 410. The photonic die 10 includes an insulating layer 103, at least one optical element 104, a deep through via 108 and an interconnect structure 113. The insulating layer 103 has a first side S1 and a second side S2 opposite to the first side S1. The at least one optical element 104 is disposed on the first side S1 of the insulating layer. The deep through via 108 penetrates through the insulating layer 103 and aside the at least one optical element 104, wherein a metal of the deep through via 108 is in direct contact with the insulating layer 103. The interconnect structure 113 is disposed over the first side S1 of the insulating layer 103 and electrically connected to the deep through via 108. The conductive connector 410 is disposed on the second side S2 of the insulating layer 103 and electrically connected to the deep through via 108. In some embodiments, a critical dimension of the deep through via 108 is between a critical dimension of the interconnect structure 113 and a critical dimension of the conductive connector 410.

In some embodiments, a bottom surface of the deep through via 108 is flush with the second side S2 of the insulating layer 103. In some embodiments, a top surface of the deep through via 108 is protruded from the first side S1 of the insulating layer 103.

In some embodiments, the deep through via 108 is connected to a metal line of the interconnect structure 113. In some embodiments, the sizes (e.g., via sizes) of the interconnect structure 113 are gradually reduced toward the deep through via 108.

In some embodiments, the deep through via 108 is connected to a under-bump metallization pad 406 of the conductive connector 410, as shown in the semiconductor structure 1b/1d of FIG. 16A and FIG. 22A.

In some embodiments, the semiconductor structure 1a/1c of FIG. 14A and FIG. 20A further includes a RDL structure 405 disposed between the conductive connector 410 and the deep through via 108, wherein the deep through via 108 is connected to a metal via of the RDL structure 405.

In some embodiments, the semiconductor structure 1a further includes a bulk oxide (e.g., light-transparent material 125) disposed in the interconnect structure 113 and above the at least one optical element 104.

In some embodiments, the at least one optical element 104 includes a grating coupler, and an optical fiber 500 is disposed above the photonic die 10 and corresponds to the grating coupler 104, as shown in FIG. 14A and FIG. 16A.

In some embodiments, the at least one optical element 104 includes an edge coupler, and an optical fiber 500 is disposed laterally aside the photonic die 10 and corresponds to the edge coupler, as shown in FIG. 20A and FIG. 22A.

In some embodiments, the semiconductor structure 1a/1b/1c/1d further includes an electronic die 20 disposed on and hybrid-bonded to the photonic die 10, and an encapsulating layer 126 disposed over the photonic die 10 and laterally encapsulating the electronic die 20. In some embodiments, the semiconductor structure 1a/1c further includes a support die 300 disposed over the electronic die 20 and has an optical lens 303 corresponding to the optical element 104 of the photonic die 10.

In view of the above, a semiconductor structure including a deep through via embedded in an insulating substrate rather than a semiconductor substrate. The deep through via of the disclosure is formed directly in the insulating substrate without forming the conventional insulating liner. The conventional insulating liner would cause charge accumulation when the deep through via is revealed by dry etching. The deep through via of the disclosure is formed with a simplified method, and is beneficial to prevent the charge accumulation issue.

In some embodiments, the deep through via of the disclosure may be applied to a photonic-electric integrated circuit (IC) package. The sidewall of the deep through via of the disclosure is surrounded by a blanket insulating material, one end of the deep through via is in contact with a dielectric material, and the opposite end of the deep through via is in contact with a polymer material. However, the disclosure is not limited thereto. In some embodiments, the deep through via of the disclosure may serve as an electric component or a bridge component for electrical connection between two dies. The sidewall of the deep through via of the disclosure is surrounded by a blanket insulating material, and opposite ends of the deep through via are in contact with an underfill material and/or an encapsulation material.

According to some embodiments, a semiconductor structure includes a photonic die and a redistribution layer structure. The photonic die includes an insulating layer, at least one optical element, a through via and an interconnect structure. The insulating layer has a first side and a second side. The at least one optical element is disposed on the first side of the insulating layer. The through via penetrates through the insulating layer and aside the at least one optical element, wherein a metal of the through via is in direct contact with the insulating layer. The interconnect structure is disposed over the first side of the insulating layer and electrically connected to the through via. The conductive connector is disposed on the second side of the insulating layer and electrically connected to the through via. In some embodiments, a critical dimension of the through via is between a critical dimension of the interconnect structure and a critical dimension of the conductive connector.

According to some embodiments, a method of forming a semiconductor structure includes the following operations. A composite substrate is provided, and the composite substrate includes a lower insulating layer, an upper insulating layer and a semiconductor layer between the lower insulating layer and the upper insulating layer. A trench is formed to penetrate through the upper insulating layer and extend into a portion of the semiconductor layer. A through via is formed in the trench, wherein a metal of the through via is in direct contact with the upper insulating layer. The lower insulating layer and the semiconductor layer are removed, until a bottom surface of the through via is exposed.

According to some embodiments, a method of forming a semiconductor structure includes following operations. A composite substrate is provided, and the composite substrate includes a lower insulating layer, an upper insulating layer and a semiconductor layer between the lower insulating layer and the upper insulating layer. At least one optical element is formed over the upper insulating layer and embedded by an isolation layer. A trench is formed to penetrate through the isolation layer and the upper insulating layer. A through via is formed in the trench, wherein a metal of the through via is in direct contact with the upper insulating layer. An interconnect structure is formed over the isolation layer and electrically connected to the through via. The lower insulating layer and the semiconductor layer are removed. A conductive connector is formed below the isolation layer and electrically connected to the through via.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a photonic die, comprising:
an insulating layer having a first side and a second side;
at least one optical element disposed on the first side of the insulating layer;
a through via penetrating through the insulating layer and aside the at least one optical element, wherein a conductive material of the through via is in direct contact with the insulating layer; and
an interconnect structure disposed over the first side of the insulating layer and electrically connected to the through via; and
a conductive connector disposed on the second side of the insulating layer and electrically connected to the through via,
wherein a critical dimension of the through via is between a critical dimension of the interconnect structure and a critical dimension of the conductive connector.

2. The semiconductor structure of claim 1, wherein a bottom surface of the through via is flush with the second side of the insulating layer.

3. The semiconductor structure of claim 1, wherein the through via is connected to a metal line of the interconnect structure.

4. The semiconductor structure of claim 1, wherein the through via is connected to a under-bump metallization pad of the conductive connector.

5. The semiconductor structure of claim 1, further comprising a redistribution layer structure disposed between the conductive connector and the through via, wherein the through via is connected to a metal via of the redistribution layer structure.

6. The semiconductor structure of claim 1, further comprising a bulk oxide disposed in the interconnect structure and above the at least one optical element.

7. The semiconductor structure of claim 1, wherein the at least one optical element comprises a grating coupler, and an optical fiber is disposed above the photonic die and corresponds to the grating coupler.

8. The semiconductor structure of claim 1, wherein the at least one optical element comprises an edge coupler, and an optical fiber is disposed laterally aside the photonic die and corresponds to the edge coupler.

9. A method of forming a semiconductor structure, comprising:
providing a composite substrate comprising a lower insulating layer, an upper insulating layer and a semiconductor layer between the lower insulating layer and the upper insulating layer;
forming a trench penetrating through the upper insulating layer and extending into a portion of the semiconductor layer;
forming a through via in the trench, wherein a metal material of the through via is in direct contact with the upper insulating layer; and
removing the lower insulating layer and the semiconductor layer, until a bottom surface of the through via is exposed.

10. The method of claim 9, wherein the bottom surface of the through via is flush with a bottom surface of the upper insulating layer.

11. The method of claim 9, wherein the through via is formed by a deposition process.

12. The method of claim 9, wherein the through via is formed by an electroplating process.

13. The method of claim 9, further comprising, after forming the through via and before removing the lower insulating layer and the semiconductor layer, forming an interconnect structure over a top surface of the through via.

14. The method of claim 13, further comprising, after removing the lower insulating layer and the semiconductor layer, forming a redistribution layer structure over the bottom surface of the through via, wherein a critical dimension of the through via is between a critical dimension of the interconnect structure and a critical dimension of the redistribution layer structure.

15. The method of claim 13, further comprising, after removing the lower insulating layer and the semiconductor layer, forming a conductive connector over the bottom surface of the through via, wherein a critical dimension of the through via is between a critical dimension of the interconnect structure and a critical dimension of the conductive connector.

16. A method of forming a semiconductor structure, comprising:
providing a composite substrate comprising a lower insulating layer, an upper insulating layer and a semiconductor layer between the lower insulating layer and the upper insulating layer;
forming at least one optical element over the upper insulating layer and embedded by an isolation layer;
forming a trench penetrating through the isolation layer and the upper insulating layer;
forming a through via in the trench, wherein a metal material of the through via is in direct contact with the upper insulating layer;
forming an interconnect structure over the isolation layer and electrically connected to the through via;
removing the lower insulating layer and the semiconductor layer; and
forming a conductive connector below the isolation layer and electrically connected to the through via.

17. The method of claim 16, wherein a bottom surface of the through via is flush with a bottom surface of the lower insulating layer after removing the lower insulating layer and the semiconductor layer.

18. The method of claim 16, further comprising forming a redistribution layer structure between the conductive connector and the through via.

19. The method of claim 16, further comprising forming a bonding structure over the interconnection structure.

20. The method of claim 19, further comprising bonding an electronic die to the bonding structure.
